(19) United States
(12) Patent Application Publication
(10) Pub. No.: US 2007/0133171 A1
(43) Pub. Date: Jun. 14, 2007

(54) Cooling system for electronic components

(76) Inventor: Kioan Cheon, Auburn, WA (US)

Correspondence Address: Barnard Intellectual Property Law, Inc., P.O. Box 58888, Seattle, WA, 98138-1888, US

(21) Appl. No.: 11/297,997

(22) Filed: Dec. 8, 2005

(51) Int. Cl. H05K 7/20

(52) U.S. Cl. 361/699

(57) ABSTRACT

Electrical components that generate heat are housed within the body (18) of a housing (12). The housing body (18) is preferably a one-piece extrusion closed at its ends by end walls (20, 22). An inlet fitting (40) in end wall (20) communicates with an adjacent end of passageway section (34). The adjacent end of passageway section (36) communicates with an outlet fitting (42). In use, a body of a cooling fluid is placed inside of the housing (12) in contact with the electronic components in the housing (12) that generate heat. A second cooling fluid is introduced into the inlet (40) and caused to flow through first the passageway section (34), then through a passageway section in end wall (22), then through the passageway section (36) in sidewall (28), and then out through the outlet fitting (42). This circulating cooling fluid removes heat from the housing (12) and the cooling fluid inside of the housing (12).

### TECHNICAL FIELD

The invention relates to cooling systems for cooling electronic components, e.g. computer components. More particularly, it relates to a cooling system characterized by a body of cooling fluid within a housing in which the electronic components are situated and by a cooling jacket in walls of the housing, or in coils inside the housing, through which a cooling fluid is circulated.

### BACKGROUND OF THE INVENTION

It is well known that computers include components that produce heat. Various types of cooling systems have been proposed for removing heat from the computer components to maintain the computer within acceptable operating temperature limits. The known systems include the systems disclosed by my U.S. Pat. No. 5,731,954, granted Mar. 24, 1998, and entitled Cooling System For Computer, by my U.S. Pat. No. 6,234,240, granted May 22, 2001, and entitled Fanless Cooling System For Computer, by my U.S. Pat. No. 6,313,990, granted Nov. 6, 2001, and entitled Cooling Apparatus For Electronic Devices, and by my U.S. Pat. No. 6,664,627, granted Dec. 19, 2003, and entitled Water Cooling Type Cooling Block For Semiconductor Chip.

The principal object of the present invention is to provide a cooling system that is especially appropriate for use with small computers, including personal computers, work stations, servers, and small mainframes, and which includes a cooling fluid in the housing in the components to be cooled are situated.

### BRIEF SUMMARY OF THE INVENTION

The cooling system of the present invention is used to cool electronic components that generate heat when they are in use. The system comprises a housing defining an interior space. At least one heat producing electronic component is in the interior space. A cooling fluid is housed within the interior space in direct contact with the heat producing electronic component. In one embodiment the housing walls include a coolant passageway that has an inlet and an outlet. In use, a cooling fluid is introduced into the passageway through the inlet, is moved through the passageway, and then is removed from the passageway through the outlet. The cooling fluid removes heat from the housing and the cooling fluid in the interior space of the housing.

In the preferred embodiment, the housing has four sidewalls comprising spaced apart first and second sidewalls and spaced apart third and fourth side walls that extend between and interconnect the first and second sidewalls. The sidewalls form end openings at the opposite ends of the housing. The housing includes first and second end walls that extend over and cover the end openings of the housing. The end walls are connected to the sidewalls.

The inlet may be at one end of the first end wall. The coolant passageway may include a first section that extends lengthwise through the first sidewall, a second section that extends lengthwise through the second end wall, and a third section that extends lengthwise through the second sidewall. The inlet may communicate with the first section of the coolant passageway. The first section of the coolant passageway may communicate with the second section of the coolant passageway. The second section of the coolant passageway may communicate with the third section of the coolant passageway. The third section of the coolant passageway may communicate with the outlet.

In a preferred embodiment, the four sidewalls are parts of an extrusion and the end walls are separate members that are connected to opposite end portions of the extrusion.

In a second embodiment, the coolant passageway in the housing walls is replaced by a coil that is inside the housing. The coil has an inlet and an outlet. A cooling fluid is introduced into the coil through the inlet, is moved through the coil, and then is removed from the coil through the outlet. The cooling fluid removes heat from the housing and the cooling fluid in the interior space of the housing.

According to an aspect of the invention, a sealing gasket is provided between each end wall and its end of the extrusion. Also, the cooling fluid in the interior space of the housing is a body of liquid.

According to another aspect of the invention, a balloon may be positioned inside the cooling liquid in the interior space. This balloon contains a compressible fluid. Expansion of the liquid cooling fluid in the interior space will contract the balloon and compress the compressible fluid in the balloon.

Other objects, advantages and features of the invention will become apparent from the description of the best mode set forth below, from the drawings, from the claims and from the principles that are embodied in the specific structures that are illustrated and described.

### BRIEF DESCRIPTION OF THE SEVERAL VIEWS OF THE DRAWINGS

Like reference numerals are used to designate like parts throughout the several views of drawing, and

FIG. 1 is a pictorial view showing a first housing for computer components in broken lines and a power supply housing in solid lines, such view showing the main body portion of the power supply housing in the first housing;

FIG. 2 is a pictorial view of the power supply housing shown in FIG. 1, such view being taken towards the outer end, the top and one side of the power supply housing;

FIG. 3 is an exploded view of the components of the power supply housing, such view being taken from the same advantage point as FIG. 2;

FIG. 4 is an enlarged scale view like FIG. 3 but of the first end wall and the body of the housing;

FIG. 5 is a pictorial view of FIG. 2, with the center portion of the housing shown in broken lines for the purpose of exposing the interior of the housing and showing the circulation of a first coolant within the housing and the circulation of a second coolant in passages in the walls of the housing;

FIG. 6 is a horizontal sectional view taken through the mechanism shown by FIGS. 1-5 at the level of the coolant passageways in the sidewalls of a housing in which electronic components are situated, such view showing arrows depicting flow through the coolant passageways in the sidewalls and arrows showing the circulation of the coolant within the interior of the housing;

FIG. 7 is an enlarged scale fragmentary sectional view of one side of FIG. 6, with the center portion cut away for the purpose of shortening the view;

FIG. 8 is a sectional view taken substantially along line 8-8 of FIG. 9; and

FIG. 9 is a sectional view taken substantially along line 9-9 of FIG. 8.

### DETAILED DESCRIPTION OF THE ILLUSTRATED EMBODIMENT

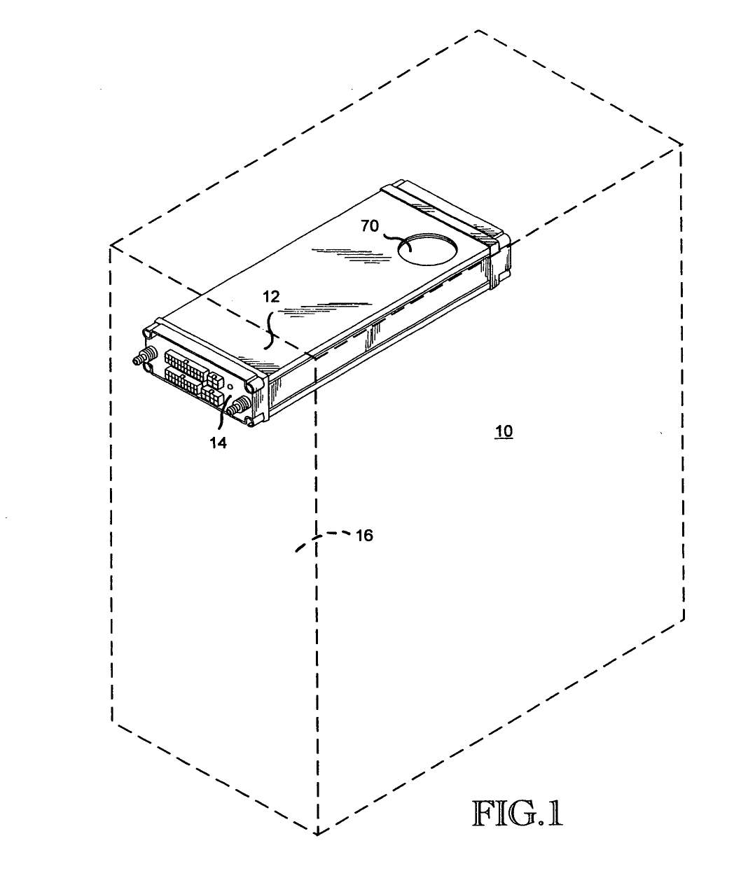

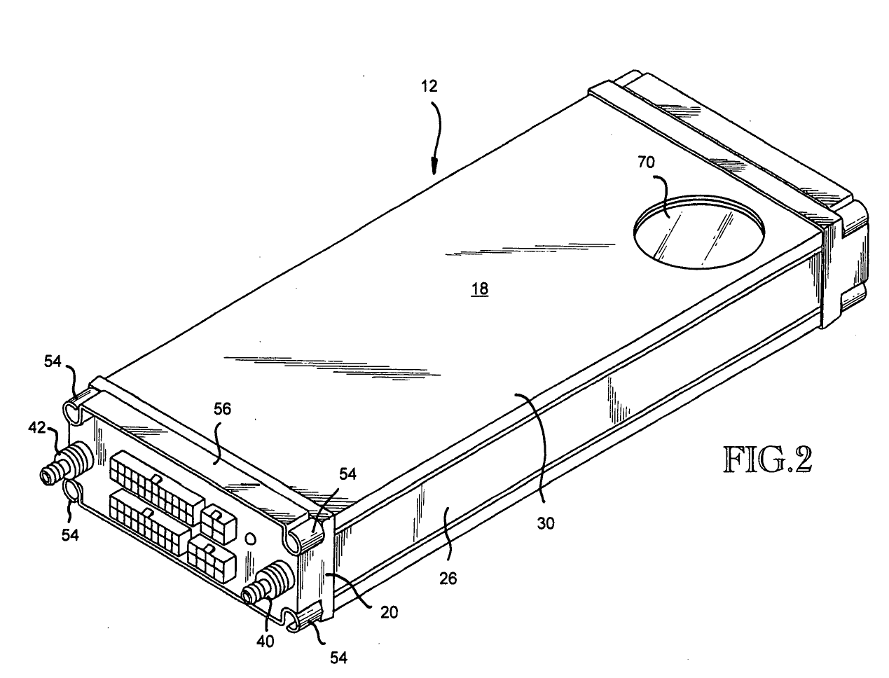

FIG. 1 shows a first or outer housing 10 for computer components. This housing 10 is comparable to the housings shown in FIG. 1 of the aforementioned U.S. Pat. No. 6,234,241 B1, and in FIGS. 1A and 1B of the aforementioned U.S. Pat. No. 6,313,990 B1. Specifically, housing 10 is comparable to the housing 6 shown in U.S. Pat. No. 6,234,240 B1 and the housing 22 in U.S. Pat. No. 6,313,990 B1. A smaller housing 12 is mounted inside of the housing 10 in any suitable manner. FIG. 1 shows the housing 12 provided with and end wall 14 that is attached to wall 16 of housing 10, such as by the use of mounting screws.

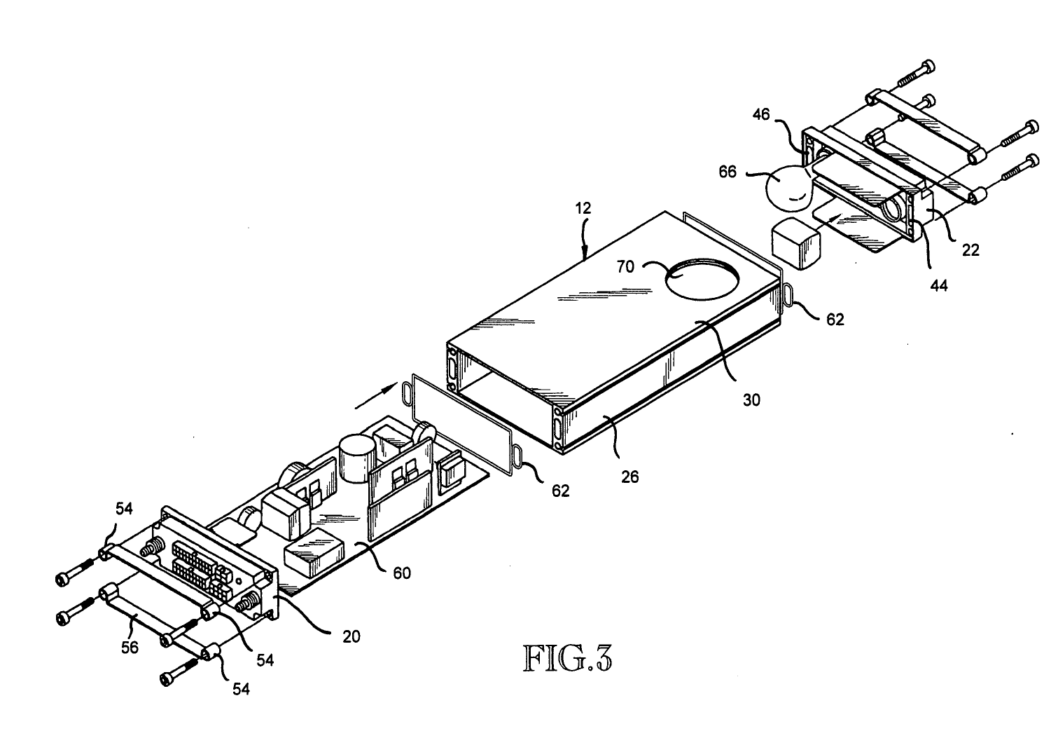

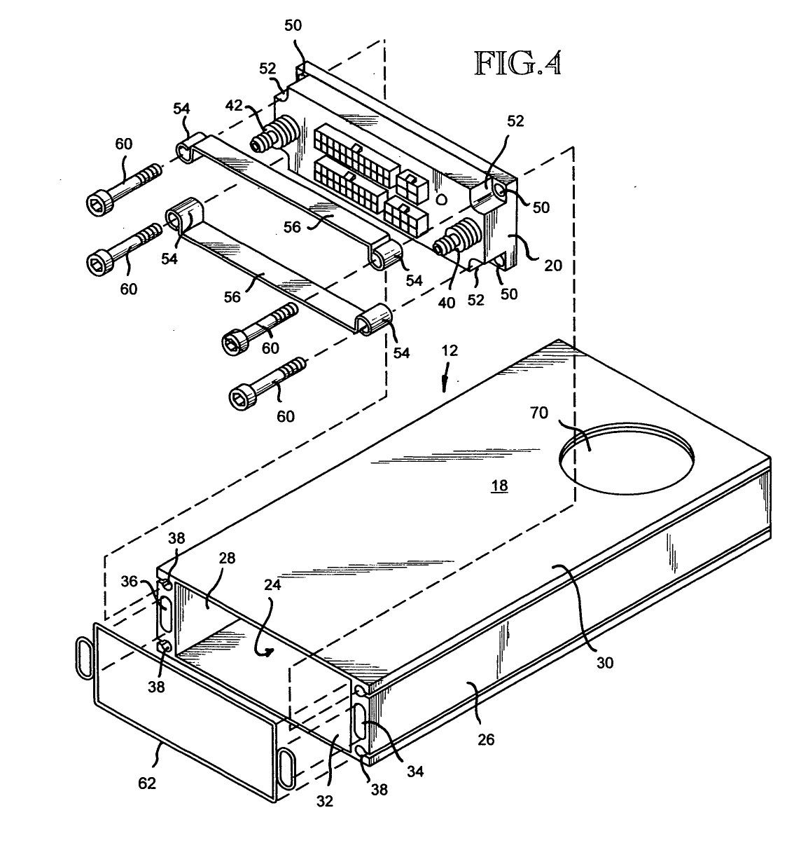

Referring to the drawing, and in particular to FIGS. 3 and 4, the housing 12 may include a main body portion 18 in the form of a one-piece extrusion, a first end wall 20 and a second end wall 22 (FIG. 3). Body portion 18 may be formed to include a center space 24 that extends the full length of the member 18, first and second sidewalls 26, 28 and third and fourth sidewalls 30, 32. The first and second sidewalls 26, 28 are spaced apart from each other. The third and fourth sidewalls 30, 32 are spaced apart from each other and they interconnect the first and second sidewalls 26, 28. All four sidewalls 26, 28, 30, 32 extend the full length of the member 18.

As clearly shown by FIGS. 3 and 4, the foreground end of body 18 is open. An identical view looking towards the opposite end of body 18 would show that it is also open. Accordingly, body 18 has open ends formed where the space 24 meets the end planes of the walls 26, 28, 30, 32. Walls 26, 28 are formed to include longitudinal passageway sections 34, 36. These passageway sections 34, 36 extend the full length of the sidewalls 26, 28. The far end of housing 18 looks like the near end that is pictured in FIGS. 3 and 4. Mounting screw receiving openings 38 are formed in at least the end portions of the sidewalls 26, 28, at both ends of the housing 18. Preferably, the fastener receiving openings 38 are formed by extruding four longitudinal grooves in the sidewalls 26, 28 as a part of the manufacture of the housing 18. The grooves may have substantially circular main portions flanked by narrow slot portions. The slot portions of the grooves extend through the sidewalls 26, 28. This construction of the grooves facilitates their formation as a part of the extrusion process.

End wall 20 may include an inlet fitting 40 and an outlet fitting 42. The fittings 40, 42 have inner end portions that thread into threaded openings formed in the end wall 20. They also include threaded outer end portions which connect to hoses or conduits which deliver a cooling fluid to the inlet 40 and move it away from the outlet 42. There are openings in the end wall 20 which connect the fittings 40, 42 with the passageways 34, 36 when the end wall 20 is connected to the main portion 18 of the housing 12.

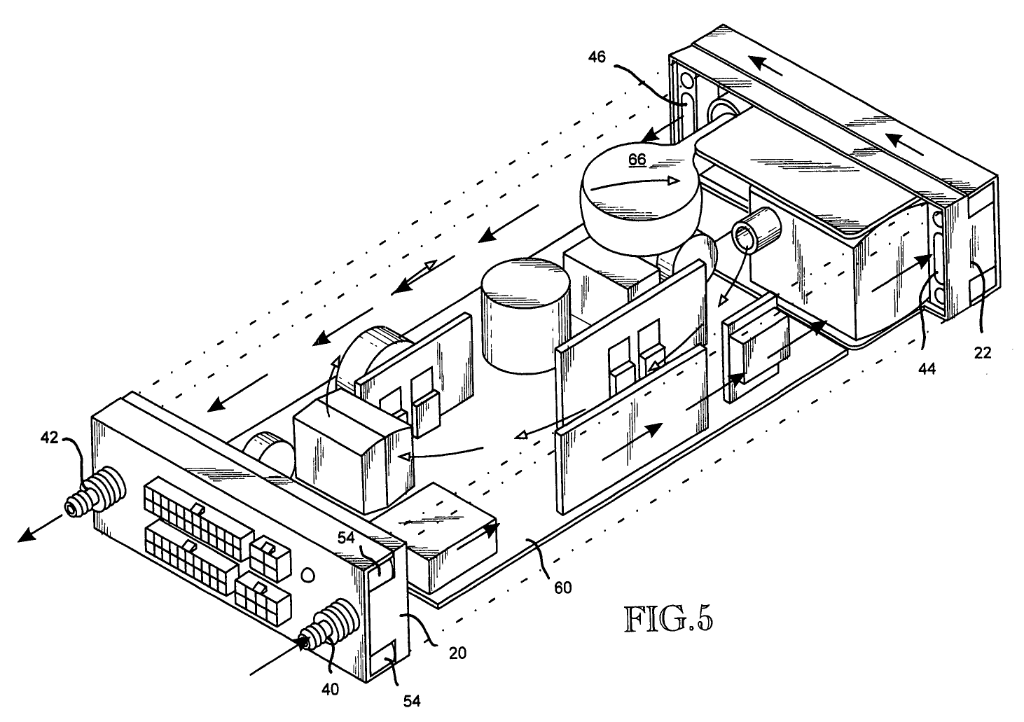

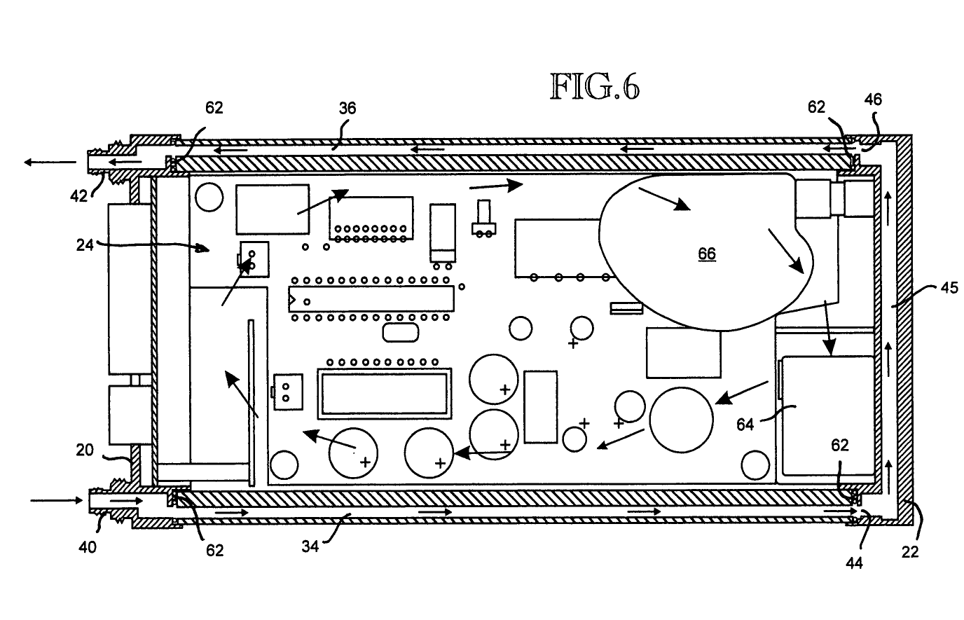

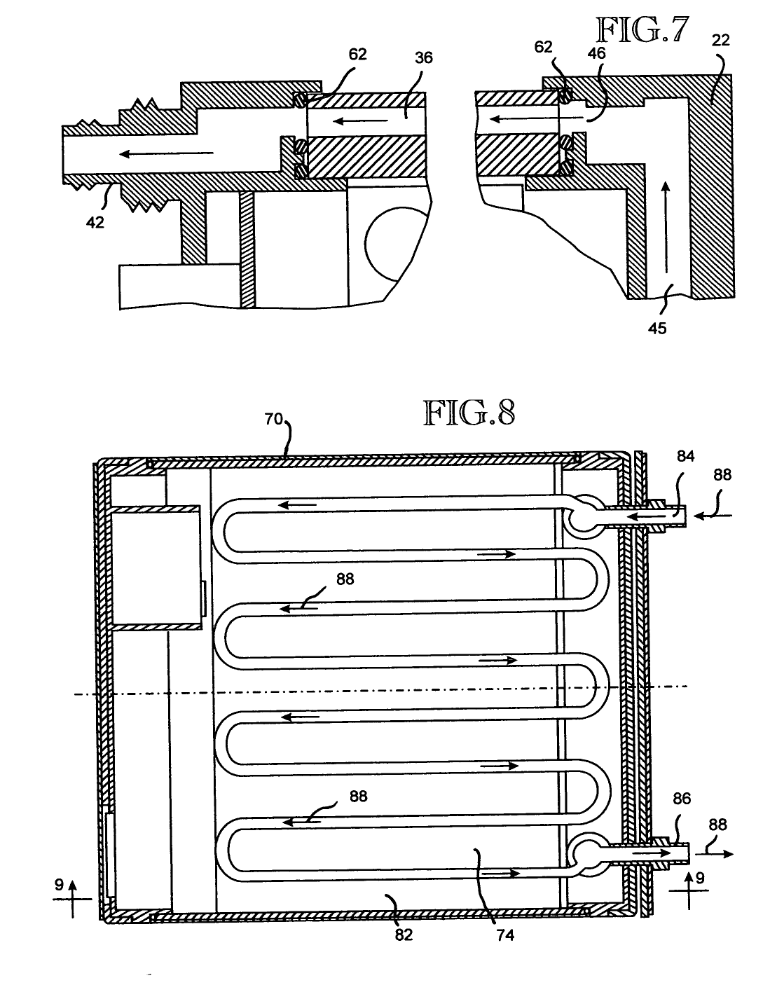

The end wall 22 is constructed similar to end wall 20. However, it does not include the fittings 40, 42. Rather, it includes ports 44, 46 that align with the passageways 34, 36 in the walls 26, 28. A transverse passageway 45 (FIG. 6) extends through the end wall 22 and interconnects the ports 40, 46. When the end walls 20, 22 are connected to the main body 18, inlet 40 communicates with passageway section 34. Passageway section 34 in turn communicates with passageway section 45 in end member 22. The passageway section 45 in end member 22 communicates with passageway 36 in sidewall 28. Passageway 36 communicates with the outlet port 42. Accordingly, as shown by arrows in FIG. 5, a cooling fluid is introduced into inlet 40 and it flows through the passageway section 34 into the passageway section 45 and then into the passageway section 36 and from it out through the outlet fitting 42. Of course, the direction of flow of the cooling fluid can be reversed if that should be desired.

The system for connecting the end walls 20, 22 to the main housing 18 is the same at both ends of the housing 12. Fastener openings 50 are formed in the four corners of the end members 20, 22. Corner recesses 52 are formed in the outer four corner portions of the end wall 20, 22. Coiled end portions 54 are formed at the ends of elongated flat bar members 56. The coiled end portions 54 are fitable in the corner recesses 52. They include center openings that are aligned with the fastener openings 50 in the end members 20, 22. Fasteners are shown in the form of machine screws 60. The threaded ends of the screws 60 are extended through the coiled end portions 54 of the members 56 and into and through the openings 50. They screw into the fastener openings 38 formed in the ends of the sidewalls 26, 28. The threads on the inner ends of the screws 60 may be self-tapping threads that screw themselves into the sidewalls of the fastener openings 38.

Referring to FIG. 3, the electronic components that are in the power supply assembly are mounted on a board 60 that slides into the body 18 of the housing 12. The electronic components are dimensioned so that they will fit within the interior space 24. Gaskets 62 (FIG. 6) are positioned between the ends of the body 18 and the end walls 20, 22. When the end walls 20, 22 are secured to the body 18, the gaskets 62 provide a fluid type seal at the opposite ends of chamber 24. A pump 64 is positioned inside the space 24. Pump 64 may be mounted on end wall 22, for example. When the parts shown in FIG. 3 and the gaskets 62 are assembled, a suitable cooling fluid 65 is introduced into the interior space 24. By way of example, the cooling fluid 65 may be a liquid fluorocarbon such as Freon in which a part or all hydrogen atoms have been replaced by fluorine atoms. The fluorocarbon is nonflammable and heat-stable. An inflatable member 66, having a flexible sidewall, is also positioned within side the interior space 24. Member 66 is like a balloon. It is inflated by an inert gas. The cooling fluid 65 fills the remaining portion of space 24. This fluid 65 is contained within the housing 12 but is preferably kept in motion by the pump 64. In other words, pump 64 pulls in coolant fluid 65 from a first direction and then discharges it back into space 24 in a second direction, as shown by the arrows in FIG. 5.

During use of the electronic device, at least some of the electronic components on board 60 generate heat. This heat is transferred to the cooling fluid 65. In the process, the electronic components are cooled and the cooling fluid 65 and the housing 12 are heated. The second cooling fluid that is circulated through the sidewalls 26, 28 and end wall 22 functions to remove heat from the housing 12 and the cooling liquid inside of it. The cooling fluid that is circulated through the walls 26, 22, 28 may be cooled by a radiator or other means before it is introduced into the inlet 40. When this cooling fluid is moved out of the outlet 42 it is returned to the radiator or other device for removing heat from it.

As the temperature of the cooling fluid in chamber 24 rises, the cooling fluid 65 will expand and want to take up more space in the housing 12. The balloon 66 allows this to happen. The expanding fluid 65 on the outside of the balloon 66 exerts an inward force on the balloon wall, contracting the balloon and compressing the fluid within the balloon 66. This reduces the amount of space taken up by the balloon 66 and allows the cooling fluid 65 inside a chamber 24 to move into the space relinquished by the contracting balloon 66.

The top wall 30 of the housing 12 may include a window 70 formed from a transparent or translucent material. This allows a person to view through the window 70 into the interior of the housing in order to check the condition of the cooling fluid 65 in the housing 12. A seal is provided between the window 70 and the housing wall 30 so that the cooling fluid 65 does not leak out of the housing 12 in the vicinity of the window 70.

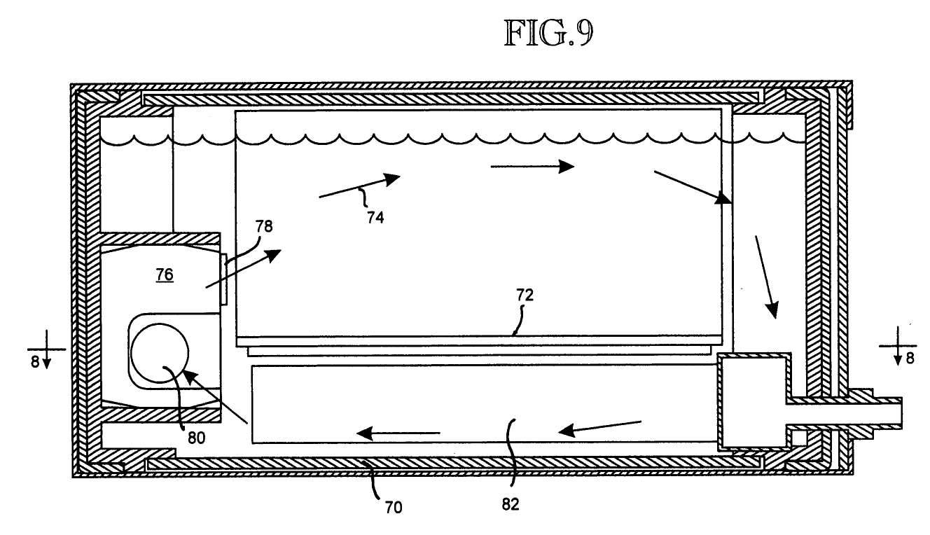

FIGS. 8 and 9 show another embodiment of the invention. It comprises a housing 70 in which the electronic components 72 are housed. As in the first embodiment the housing 70 includes a coolant 74 that is circulated by a pump 76. The pump 76 discharges the coolant 74 through an outlet 78, causing it to circulate in the direction of the arrows. The fluid 74 flows across the upper portion of the housing 70, then downwardly, and then back to an inlet 80 leading back into the pump 76. In this embodiment, the cooling fluid passageway in the sidewalls of the housing is replaced by a coil 82 which may be housed in a lower portion of the housing 70. Coil 82 includes an inlet 84 and an outlet 86. As clearly shown by FIG. 8, the coil 82 goes back and forth against the housing 70 and includes a passageway through which a coolant 88 flows. The coolant 88 enters into the coil 82 through the inlet 84. It flows through the coil 82 and then out from the outlet 86. A radiator or other suitable device for cooling the coolant 88 after it leaves the outlet 86 and before it enters the inlet 84 is provided. This fluid cooling mechanism may be of any suitable construction for removing heat from the coolant in some location between the outlet 86 and the inlet 84. The embodiments shown by FIGS. 8 and 9 may include an inflatable device 66 that serves the same purpose as to device 66 in the first embodiment.

The illustrated embodiment is only one example of the present invention and, therefore, is non-limitive. It is to be understood that many changes in the particular structure, materials and features of the invention may be made without departing from the spirit and scope of the invention. Therefore, it is my intention that my patents rights not be limited by the particular embodiment that is illustrated and described herein, but rather is to be determined by the following claims, interpreted according to accepted doctrines of patent claim interpretation, including use of the doctrine of equivalents.

What is claimed is:

1. A cooling system for an electronic device, comprising:
a housing defining an interior space;
at least one heat producing electronic component mounted in said interior space;
said housing comprising sidewalls and end walls, and a coolant passageway extending from an inlet in one end wall, through a sidewall to the second end wall, through the second end wall to a second sidewall, and through the second sidewall back to an outlet in the first end wall;
a cooling liquid in the interior space in contact with the heat producing electronic component; and
a cooling fluid in the coolant passageway;
wherein said cooling liquid is adapted to remove heat from the heat producing electronic component inside the housing, and said cooling fluid is adapted to remove heat from the housing and from the cooling liquid in the interior space.

2. The cooling system of claim 1, wherein the housing has four sidewalls comprising spaced apart first and second sidewalls and spaced apart third and forth sidewalls that extend between and interconnect the first and second sidewalls, said sidewalls forming end openings at the opposite ends of the housing.

3. The cooling system of claim 2, wherein the end walls extend over and cover the end openings and are connected to the sidewalls.

4. The cooling system of claim 3, wherein the inlet is at one end of the first end wall and the coolant passageway includes a first section that extends lengthwise through the first sidewall, a second section that extends lengthwise through the second end wall, and a third section that extends lengthwise through the second sidewall, wherein the inlet communicates with the first section of the coolant passageway, and said first section of said coolant passageway communicates with the second section of the coolant passageway, and said second section of the coolant passageway communicates with the third section of the coolant passageway, and said third section of the coolant passageway communicates with the outlet.

5. The system of claim 1, wherein the four sidewalls are portions of an extrusion and the end walls are separate members connected to opposite end portions of the extrusion.

6. The cooling system of claim 5, comprising a gasket positioned between each end wall and its end of the extrusion.

7. The cooling system of claim 1, wherein the cooling fluid in the interior space is a liquid.

8. The cooling system of claim 2, wherein the cooling fluid in the interior space is a liquid.

9. The cooling system of claim 3, wherein the cooling fluid in the interior space is a liquid.

10. The cooling system of claim 4, wherein the cooling fluid in the interior space is a liquid.

11. The cooling system of claim 5, wherein the cooling fluid in the interior space is a liquid.

12. The cooling system of claim 6, wherein the cooling fluid in the interior space is a liquid.

13. The cooling system of claim 7, comprising a balloon extending into the cooling liquid in the interior space, said balloon containing a compressible fluid, wherein expansion of the liquid cooling fluid in the interior space will contract the balloon and compress the compressible fluid in the balloon.

14. The cooling system of claim 8, comprising a balloon extending into the cooling liquid in the interior space, said balloon containing a compressible fluid, wherein expansion of the liquid cooling fluid in the interior space will contract the balloon and compress the compressible fluid in the balloon.

15. The cooling system of claim 9, comprising a balloon extending into the cooling liquid in the interior space, said balloon containing a compressible fluid, wherein expansion of the liquid cooling fluid in the interior space will contract the balloon and compress the compressible fluid in the balloon.

16. The cooling system of claim 10, comprising a balloon extending into the cooling liquid in the interior space, said balloon containing a compressible fluid, wherein expansion of the liquid cooling fluid in the interior space will contract the balloon and compress the compressible fluid in the balloon.

17. The cooling system of claim 11, comprising a balloon extending into the cooling liquid in the interior space, said balloon containing a compressible fluid, wherein expansion of the liquid cooling fluid in the interior space will contract the balloon and compress the compressible fluid in the balloon.

18. The cooling system of claim 12, comprising a balloon extending into the cooling liquid in the interior space, said balloon containing a compressible fluid, wherein expansion of the liquid cooling fluid in the interior space will contract the balloon and compress the compressible fluid in the balloon.

19. The cooling system of claim 1, wherein the cooling fluid in the interior space a fluorocarbon.

20. The cooling system of claim 19, comprising a balloon extending into the cooling liquid in the interior space, said balloon containing a compressible fluid.

21. A cooling system for an electronic device, comprising:
a housing defining an interior space;
at least one heat-producing electronic component mounted in said interior said space;
a cooling fluid in the interior space in contact with the heat-producing electronic component;
a coolant passageway in the housing having an inlet and an outlet; and
a cooling fluid in the coolant passageway;
wherein said cooling liquid is adapted to remove heat from the heat-producing electronic component inside the housing, and said cooling fluid is adapted to remove heat from the cooling liquid in the interspace.

22. The cooling system of claim 21, wherein the coolant passageway is a coil structure inside of the housing, and the inlet extends through a wall of the housing and connects to the coil and the outlet connects to the coil and extends outwardly through a wall of the housing.
